(19) United States
(12) Patent Application Publication
(10) Pub. No.: US 2023/0260802 A1
(43) Pub. Date: Aug. 17, 2023

(54) HIGHLY SELECTIVE SILICON ETCHING

(71) Applicant: Applied Materials, Inc., Santa Clara, CA (US)

(72) Inventors: Daekyoung Kim, San Jose, CA (US); Ho Jeong Kim, San Jose, CA (US); Byungkook Kong, Newark, CA (US); Sangwook Kim, Palo Alto, CA (US)

(73) Assignee: Applied Materials, Inc., Santa Clara, CA (US)

(21) Appl. No.: 17/674,127

(22) Filed: Feb. 17, 2022

(51) Int. Cl. H01L 21/3213; H01L 21/02; H01L 21/67

(52) U.S. Cl. CPC H01L 21/32137; H01L 21/02126; H01L 21/02532; H01L 21/67248

(57) ABSTRACT

Exemplary semiconductor processing methods may include providing a fluorine-containing precursor and a hydrogen-containing precursor to a processing region of a semiconductor processing chamber. A substrate may be disposed within the processing region of the semiconductor processing chamber. The substrate may include at least one layer of silicon-containing material and at least one layer of silicon-and-germanium-containing material along the substrate. The methods may include forming a plasma of the fluorine-containing precursor and the hydrogen-containing precursor within the processing region. The methods may include contacting the at least one layer of silicon-containing material and the at least one layer of silicon-and-germanium-containing material with plasma effluents of the fluorine-containing precursor and the hydrogen-containing precursor. The methods may include removing the at least one layer of silicon-containing material at a higher rate than the at least one layer of silicon-and-germanium-containing material.

### TECHNICAL FIELD

The present technology relates to semiconductor systems, processes, and equipment. More specifically, the present technology relates to processes and systems to selectively etch silicon material relative to silicon-and-germanium material.

### BACKGROUND

Integrated circuits are made possible by processes which produce intricately patterned material layers on substrate surfaces. Producing patterned material on a substrate requires controlled methods for forming and removing material. Memory, including stacked memory, such as vertical or 3D NAND, as well as transistor structures including finFET and gate all around, may include many layers and materials that may be processed to include selective removal of some materials while other are maintained. Material properties of the layers of materials, as well as process conditions and materials for etching, may affect the uniformity of the formed structures. Material defects may lead to inconsistent patterning, which may further affect the uniformity of the formed structures.

Thus, there is a need for improved systems and methods that can be used to produce high quality devices and structures. These and other needs are addressed by the present technology.

### SUMMARY

Exemplary semiconductor processing methods may include providing a fluorine-containing precursor and a hydrogen-containing precursor to a processing region of a semiconductor processing chamber. A substrate may be disposed within the processing region of the semiconductor processing chamber. The substrate may include at least one layer of silicon-containing material and at least one layer of silicon-and-germanium-containing material along the substrate. The methods may include forming a plasma of the fluorine-containing precursor and the hydrogen-containing precursor within the processing region. The methods may include contacting the at least one layer of silicon-containing material and the at least one layer of silicon-and-germanium-containing material with plasma effluents of the fluorine-containing precursor and the hydrogen-containing precursor. The methods may include removing the at least one layer of silicon-containing material at a higher rate than the at least one layer of silicon-and-germanium-containing material.

In some embodiments, the fluorine-containing precursor may be or include one or both of nitrogen trifluoride and carbon tetrafluoride. The at least one layer of silicon-containing material may be selectively removed relative to the at least one layer of silicon-and-germanium-containing material at a rate of greater than or about 2:1. The plasma of the fluorine-containing precursor and the hydrogen-containing precursor may be generated at a source plasma power of less than or about 1,000 W. A bias applied to the plasma of the fluorine-containing precursor and the hydrogen-containing precursor may be generated at a bias power of less than or about 100 W. The plasma of the fluorine-containing precursor and the hydrogen-containing precursor may be generated at a duty cycle of less than or about 50%. The methods may include pulsing the source plasma power while forming plasma effluents of the fluorine-containing precursor and the hydrogen-containing precursor. The source plasma power may be pulsed at a frequency of less than or about 1000 Hz. A temperature within the semiconductor processing chamber may be maintained at less than or about 125° C. A pressure within the semiconductor processing chamber may be maintained at less than or about 200 mTorr. The methods may include providing an inert precursor to the processing region of the semiconductor processing chamber with the fluorine-containing precursor and the hydrogen-containing precursor. The inert precursor may be or include a nitrogen-containing inert precursor, an argon-containing inert precursor, a helium-containing inert precursor, or combinations thereof. A flow rate ratio of the hydrogen-containing precursor to the fluorine-containing precursor may be greater than or about 2:1. The plasma may be oxygen-free.

Some embodiments of the present technology may encompass semiconductor processing methods. The methods may include providing a fluorine-containing precursor, a hydrogen-containing precursor, and a nitrogen-containing precursor. The methods may include forming a plasma of the fluorine-containing precursor, the hydrogen-containing precursor, and the nitrogen-containing precursor. The methods may include contacting at least one layer of silicon-containing material and at least one layer of silicon-and-germanium-containing material along a substrate with plasma effluents of the fluorine-containing precursor, the hydrogen-containing precursor, and the nitrogen-containing precursor. The contacting may selectively remove the at least one layer of silicon-containing material.

In some embodiments, the fluorine-containing precursor may be or include carbon tetrafluoride. The nitrogen-containing precursor may be or include nitrogen trifluoride. The fluorine-containing precursor and the nitrogen-containing precursor may form a passivation compound and an etch compound when contacting the at least one layer of silicon-containing material and the at least one layer of silicon-and-germanium-containing material. The passivation compound may include carbon, hydrogen, and fluorine materials. The etch compound may include nitrogen, hydrogen, and fluorine materials. A pressure may be maintained at less than or about 70 mTorr during the semiconductor processing method. The at least one layer of silicon-and-germanium-containing material may be characterized by a germanium concentration of less than or about 50 at. %. The etch compound may remove the at least one layer of silicon-containing material relative to the at least one layer of silicon-and-germanium-containing material at a selectivity of greater than or about 3:2. The methods may include providing a hydrogen-containing precursor and an inert precursor with the fluorine-containing precursor and the nitrogen-containing precursor. The fluorine-containing precursor, the nitrogen-containing precursor, the hydrogen-containing precursor, and an inert precursor may form the passivation compound and the etch compound. The passivation compound may passivate the at least one layer of silicon-and-germanium-containing material. The etch compound may remove the at least one layer of silicon-containing material.

Some embodiments of the present technology may encompass semiconductor processing methods. The methods may include providing a fluorine-containing precursor and a nitrogen-containing precursor to a processing region of a semiconductor processing chamber. A substrate may be disposed within the processing region of the semiconductor processing chamber. The substrate may include at least one layer of silicon-containing material and at least one layer of silicon-and-germanium-containing material along the substrate. The methods may include forming a plasma of the fluorine-containing precursor and the nitrogen-containing precursor within the processing region. The plasma may be generated at a discontinuous plasma power of less than or about 1,000 W. The methods may include contacting the at least one layer of silicon-containing material and the at least one layer of silicon-and-germanium-containing material with plasma effluents of the fluorine-containing precursor and the nitrogen-containing precursor. The contacting may passivate the at least one layer of silicon-and-germanium-containing material. The methods may include removing the at least one layer of silicon-containing material at a higher rate than the at least one layer of silicon-and-germanium-containing material. The at least one layer of silicon-containing material may be selectively removed relative to the at least one layer of silicon-and-germanium-containing material at a rate of greater than or about 3:2.

Such technology may provide numerous benefits over conventional methods and techniques. For example, the processes may passivate a material to further limit etching, such as a silicon-and-germanium material, which may result in selective etching of a second material, such as a silicon material. Additionally, due to the passivation of one material, the processes may allow for the two different materials to be closer in stoichiometry and, thereby, reduce strain between the two materials. Moreover, the processes may not utilize oxygen which may oxidize one or more of the layers of material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic cross-sectional view of an exemplary processing system according to some embodiments of the present technology.

FIG. 3 shows selected operations in a semiconductor processing method according to some embodiments of the present technology.

FIGS. 4A-4B show exemplary schematic cross-sectional structures in which material layers are included and produced according to some embodiments of the present technology.

FIGS. 5A-5B show graphical representations of selected operating characteristics relative to etch selectivity according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Many integrated circuit applications require selective removal of one material relative to another material. For example, memory structures and gate-all-around devices may require the selective removal of silicon material relative to silicon-and-germanium material adjacent to the silicon material. During fabrication of memory structures and gate-all-around devices, a stack of materials may be developed, and which may include adjacent layers of silicon material and silicon-and-germanium material. Subsequent steps of fabrication may seek to remove the silicon material selectively with respect to the silicon-and-germanium material. An etch process may be used to remove the silicon material, which may be or include silicon, while seeking to limit removal of the silicon-and-germanium material, which may be silicon germanium. Due to the chemical similarity of silicon and silicon-and-germanium, maintaining a high etch selectivity of silicon removal relative to silicon-and-germanium removal may be difficult. Various precursors and operating conditions have been employed to increase the etch selectivity.

As semiconductor processing seeks to utilize more materials to provide improved patterning and material characteristics for a range of devices, silicon-and-germanium is being increasingly used as a material for end devices as well as patterning other materials, including silicon. Conventional technologies have struggled to selectively remove silicon material relative to silicon-and-germanium material, and have typically been limited to etch rates close to 1:1, especially for material layers having lower germanium incorporation, such as below or about 50%. Removal of the silicon material may cause excessive loss of portions of silicon-and-germanium material. The removal of silicon-and-germanium material may result in material defects which may lead to uniformity issues that ultimately affect final devices. Furthermore, conventional technologies may require operating at high pressures and using precursors with oxygen in an attempt to increase selectivity. The high pressures may cause a more isotropic etch profile, which can affect device structures and produce particles. Additionally, the presence of oxygen may cause the remaining materials to at least partially oxidize, which can reduce charge carrier mobility, and detrimentally impact device performance. Accordingly, many conventional technologies have been limited in the ability to prevent structural flaws or reduced performance in the final devices.

The present technology overcomes these issues by utilizing particular precursors that may be delivered under more specific operating conditions, which may boost silicon selectivity while advantageously allowing etching to be performed at lower pressures and without oxygen-containing precursors. By providing certain precursor combinations, the present technology may be able to at least partially passivate or protect one of the layers of material from being removed during processing while another layer of material may more readily be removed. Further, by passivating or protecting one of the layers of material from being removed during processing, the present technology may allow structures to be developed in which adjacent layers may be characterized by more similar chemical composition, which may reduce strain developed between the layers during formation, while producing increased selectivity for removal.

Although the remaining disclosure will routinely identify specific etching processes utilizing the disclosed technology, it will be readily understood that the systems and methods are equally applicable to a variety of other processes as may occur in the described chambers. Accordingly, the technology should not be considered to be so limited as for use with the described etching processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed may be performed in any number of processing chambers and systems.

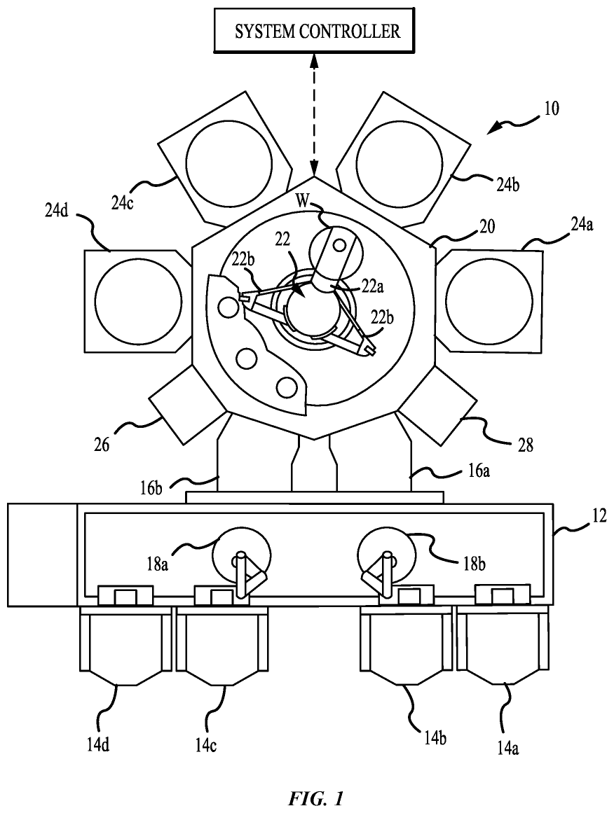

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

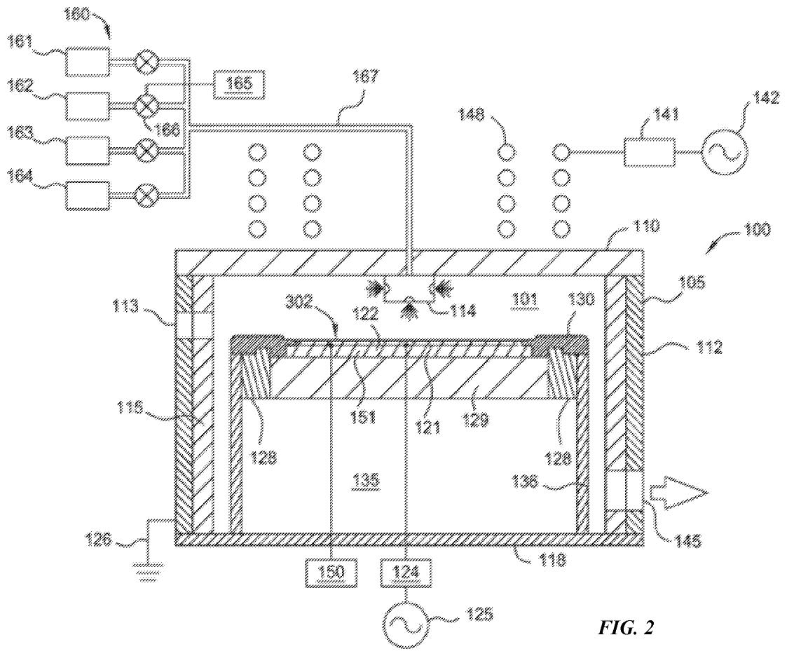

FIG. 2 illustrates a schematic cross-sectional view of an exemplary processing chamber 100 suitable for patterning a material layer disposed on a substrate 302 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 302 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 302 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as BCl₃, CF₄, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 302 during processing. The substrate support pedestal 135 may include an electrostatic chuck 122 for holding the substrate 302 during processing. The electrostatic chuck (“ESC”) 122 may use the electrostatic attraction to hold the substrate 302 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 302 seated on the pedestal. The RF power supply 125 may cycle on and off, or pulse, during processing of the substrate 302. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 200 volts to about 2000 volts to the electrode 121. The power source 150 may also include a system controller for controlling the operation of the electrode 121 by directing a DC current to the electrode 121 for chucking and de-chucking the substrate 302. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 302 disposed thereon. The ESC 122 may be configured to perform in the temperature range required by the thermal budget of the device being fabricated on the substrate 302. For example, the ESC 122 may be configured to maintain the substrate 302 at a temperature of about −150° C. or lower to about 500° C. or higher depending on the process being performed.

The cooling base 129 may be provided to assist in controlling the temperature of the substrate 302. To mitigate process drift and time, the temperature of the substrate 302 may be maintained substantially constant by the cooling base 129 throughout the time the substrate 302 is in the cleaning chamber. In some embodiments, the temperature of the substrate 302 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 302, while shielding the top surface of the substrate support pedestal 135 from the plasma environment inside the plasma processing chamber 100. Lift pins may be selectively translated through the substrate support pedestal 135 to lift the substrate 302 above the substrate support pedestal 135 to facilitate access to the substrate 302 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

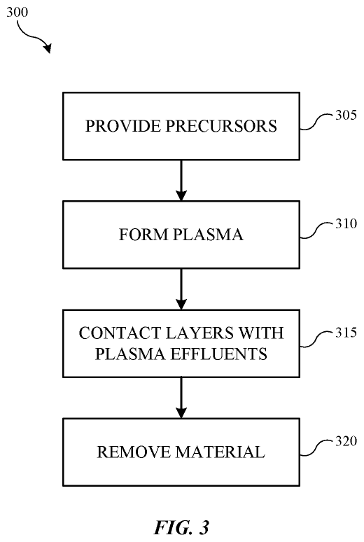

The processing chambers described above may be used during methods according to embodiments of the present technology. FIG. 3 illustrates a method 300 of semiconductor processing, operations of which may be performed, for example, in one or more chambers 100 incorporated on multi-chamber processing system 10 as previously described. Any other chamber may also be utilized, which may perform one or more operations of any method or process described. Method 300 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

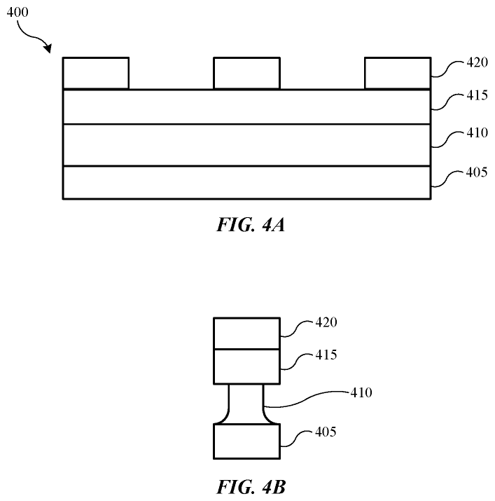

Method 300 may include a number of operations that may be performed in a number of variations, such as including beginning at different operations of processing. Method 300 may generally include an etching operation. Although method 300 will be described in a particular order, it is to be understood that the method may be performed in a number of different variations according to embodiments of the present technology. Method 300 may describe operations shown schematically in FIGS. 4A-4B, the illustrations of which will be described in conjunction with the operations of method 300. It is to be understood that structure 400 in FIGS. 4A-4B illustrates only partial schematic views, and a substrate 405 may contain any number of structural sections having aspects as illustrated in the figures, as well as alternative structural aspects that may still benefit from operations of the present technology.

Referring to FIG. 4A, the structure 400 may include a substrate 405. The substrate 405 may be disposed within the processing region of the semiconductor processing chamber. Substrate 405 may have a substantially planar surface or an uneven surface in embodiments. The substrate 405 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 405 may have various dimensions, such as 200 mm or 300 mm diameter wafers, as well as rectangular or square panels. One or more layers of material may be formed along the substrate 405. As illustrated, the substrate 405 may include at least one layer of silicon-containing material 410 and at least one layer of silicon-and-germanium-containing material 415. However, it is also contemplated that the layers of material may be switched such that the at least one layer of silicon-and-germanium-containing material 415 is positioned between the substrate 405 and the at least one layer of silicon-containing material 410. Additional layers may also be formed on the substrate 405. For example, the layers of silicon material and silicon-and-germanium material may be included in any number of layers and in any configuration, such as layers for a gate all around formation having any number of wires, or for memory structures, such as within 3D NAND topography. In any number of embodiments, an additional layer of material 420 may be deposited above the at least one layer of silicon-and-germanium-containing material 415, or a layer of silicon-containing material for patterning or other operations. The additional layer of material 420 may be a photoresist material in some embodiments of the present technology.

The at least one layer of silicon-and-germanium-containing material 415 may be characterized by any germanium concentration, although in some embodiments the material may be characterized by a germanium concentration of less than or about 50 at. %. Conventional technologies have been incapable of selectively etching silicon relative to silicon-and-germanium-containing material characterized by a germanium concentration of less than or about 50 at. % due to chemical similarity between silicon material, such as polysilicon or amorphous silicon, and silicon-and-germanium material, including silicon germanium. When silicon and silicon germanium are typically exposed to etchants, the etch selectivity may reduce as the amount of Si—Si bonding increases in the silicon-and-germanium material, based on the reduced germanium concentration. However, precursors of the present technology, as further described below, may passivate the at least one layer of silicon-and-germanium-containing material 415 and increase the etch selectivity of the at least one layer of silicon-containing material 410 relative to the at least one layer of silicon-and-germanium-containing material 415, which may allow the technology to be applied to layers characterized by reduced germanium concentration. Accordingly, the at least one layer of silicon-and-germanium-containing material 415 may be characterized by a germanium concentration of less than or about 45 at. %, less than or about 40 at. %, less than or about 35 at. %, less than or about 30 at. %, less than or about 25 at. %, less than or about 20 at. %, less than or about 15 at. %, or less. In embodiments, the at least one layer of silicon-and-germanium-containing material 415 may be characterized by a germanium concentration of greater than 50 at. %, which may result in increased etch selectivity due to the increased amount of germanium and, therefore, difference from the at least one layer of silicon-containing material 410.

At operation 305, the method 300 may include providing one or more precursors. The precursors may be provided to a processing region of a semiconductor processing chamber. The method 300 may include providing a fluorine-containing precursor, a hydrogen-containing precursor, and/or a nitrogen-containing precursor. Fluorine-containing precursors that may be used in operation 305 may be or include any number of fluorine-containing precursors. For example, the fluorine-containing precursor may be or include, nitrogen trifluoride (NF₃), carbon tetrafluoride (CF₄), fluoromethane (CH₃F), difluoromethane (CH₂F₂), fluoroform (CHF₃), any compound having carbon and fluorine, or any other fluorine compound, including fluorine-containing compounds that may not include oxygen. In embodiments, the fluorine-containing precursor may include both of NF₃ and CF₄. By introducing carbon, such as CF₄, the at least one layer of silicon-and-germanium-containing material 415 may be passivated and more resistant to etching, as will be further described below. Hydrogen-containing precursors that may be used in operation 305 may be or include any number of hydrogen-containing precursors. Hydrogen-containing precursors may include diatomic hydrogen (H₂), hydrazine (N₂H₄), methane (CH₄), or any other hydrogen compound, including hydrogen-containing precursors that may not include oxygen. Nitrogen-containing precursors that may be used in operation 305 may be or include any number of nitrogen-containing precursors. Nitrogen containing precursors may include diatomic nitrogen (N₂), ammonia (NH₃), NF₃, or any other nitrogen compound that may not include oxygen, although nitrogen compounds may include oxygen in some embodiments, such as nitrous oxide, nitric oxide, or other compounds. In some embodiments any number of additional carrier gases may be included, such as helium, argon, or any other material to help plasma stability or generation, although the precursors utilized in embodiments may be limited to one or more fluorine-containing precursors, a hydrogen-containing precursor, and/or a nitrogen-containing precursor as noted above.

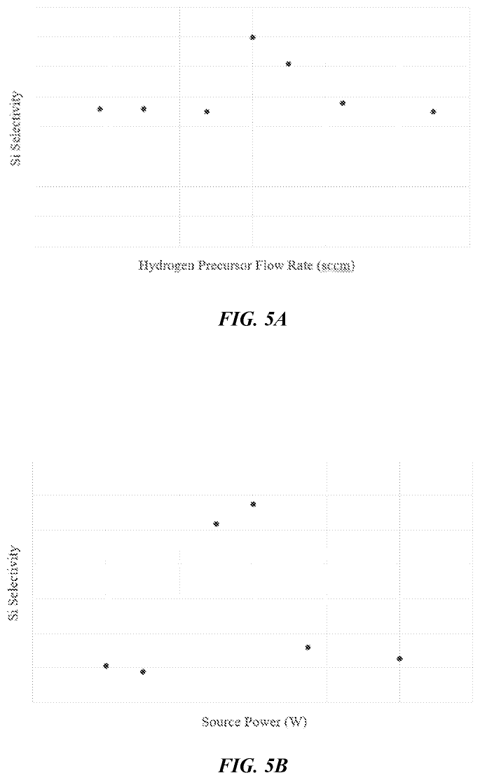

A flow rate ratio of the hydrogen-containing precursor to any or all of the fluorine-containing precursors may be greater than or about 2.0:1, which may enable a polymerization reaction that aids in passivation of silicon-and-germanium material. At flow rate ratios less than 2.0:1, the plasma may not have sufficient hydrogen to passivate the at least layer of one layer of silicon-and-germanium-containing material 415. As further described below, the precursors may interact and form a material having carbon, hydrogen, and fluorine on the at least one layer of silicon-and-germanium-containing material 415. The carbon, hydrogen, and fluorine material may protect the at least one layer of silicon-and-germanium-containing material 415 from being removed during subsequent processing. Accordingly, the flow rate ratio of the hydrogen-containing precursor to the fluorine-containing precursor may be greater than or about 2.5:1, greater than or about 3.0:1, greater than or about 3.5:1, greater than or about 4.0:1, or more compared to each fluorine-containing precursor, although the flow rate ratio may be less than or about 2.0:1 of a total flow rate of fluorine-containing precursors, such as for the example of utilizing both carbon tetrafluoride and nitrogen trifluoride, and the flow rate ratio may be less than or about 1.8:1, less than or about 1.6:1, less than or about 1.5:1, less than or about 1.4:1, or less, than the combined flow rate of all fluorine-containing precursors. In some embodiments the hydrogen-containing flow rate may be controlled within a range to enhance selectivity between silicon-containing materials and silicon-and-germanium-containing materials. As shown in FIG. 5A, at certain hydrogen-containing precursor flow rates, the etch selectivity may be higher than at lower and/or higher hydrogen-containing precursor flow rates. For example, at flow rate ratios of the hydrogen-containing precursor to any individual fluorine-containing precursor less than or about 2.0:1, the etch selectivity may decrease due to lower polymerization activity, among other aspects. Similarly, at flow rate ratios greater than or about, for example, 6.0:1 of any individual fluorine-containing precursor, the etch selectivity may decrease due to effects on etchant generation and plasma makeup. Accordingly, hydrogen-containing precursor flow rates and, thus, flow rate ratios of the hydrogen-containing precursor to the fluorine-containing precursor between about 2.0:1 and about 6.0:1 may provide higher etch selectivity.

A flow rate of any individual fluorine-containing precursor may be greater than or about 20 sccm. The flow rate of the fluorine-containing precursor may be measured as the cumulative flow rate of all fluorine-containing precursors. At combined fluorine-containing precursor flow rates of less than 40 sccm, sufficient fluorine may not be present to passivate the at least layer of one layer of silicon-and-germanium-containing material 415 and/or etch the at least one layer of silicon-containing material 410, and may increase the time for etching, which may reduce selectivity by increasing the time of exposure to etchants for the silicon-and-germanium-containing material. Accordingly, the combined flow rate of the fluorine-containing precursors may be greater than or about 50 sccm, greater than or about 60 sccm, greater than or about 70 sccm, greater than or about 80 sccm, greater than or about 90 sccm, greater than or about 100 sccm, greater than or about 110, sccm, or more. Further, the flow rate of the fluorine-containing precursor may be tailored on the amount of passivation and/or etching desired in individual applications.

A flow rate of the hydrogen-containing precursor may be greater than or about 40 sccm. The flow rate of the hydrogen-containing precursor may be measured as the cumulative flow rate of all hydrogen-containing precursors. At flow rates of less than 40 sccm, sufficient hydrogen may not be present to facilitate polymerization to passivate the at least layer of one layer of silicon-and-germanium-containing material 415 and/or etch the at least one layer of silicon-containing material 410. Accordingly, the flow rate of the hydrogen-containing precursor may be greater than or about 50 sccm, greater than or about 60 sccm, greater than or about 70 sccm, greater than or about 80 sccm, greater than or about 90 sccm, greater than or about 100 sccm, greater than or about 110, sccm, greater than or about 120 sccm, greater than or about 130 sccm, greater than or about 140 sccm, greater than or about 150, sccm, greater than or about 160 sccm, greater than or about 170 sccm, greater than or about 180 sccm, greater than or about 190, sccm, greater than or about 200 sccm, greater than or about 210 sccm, greater than or about 220 sccm, or more. Further, the flow rate of the hydrogen-containing precursor may be tailored on the amount of passivation and/or etching desired in individual applications.

A flow rate ratio of the nitrogen-containing precursor to the fluorine-containing precursor may be greater than or about 1:5. At flow rates ratios less than 1:5, sufficient nitrogen may not be present to passivate the at least layer of one layer of silicon-and-germanium-containing material 415 and/or etch the at least one layer of silicon-containing material 410. Accordingly, the flow rate ratio of the nitrogen-containing precursor to the fluorine-containing precursor may be greater than or about 1:4, greater than or about 1:3, greater than or about 1:2, greater than or about 1:1, greater than or about 3:2, or more.

In embodiments, one or more inert precursors or carrier gases may also be provided at operation 305. In embodiments, the inert precursor may be or include argon, helium, or any other noble or inert material. In embodiments using argon compared to helium, the etch selectivity may increase due to the reduced activation energy of argon compared to helium. The reduced activation energy of argon may result from the high ion bombardment energy of argon, which may increase overall etch rates facilitating etch processes.

In embodiments, a flow rate of the inert precursor may be less than the flow rate of the fluorine-containing precursor or may be greater than a flow rate of the fluorine-containing precursor. In embodiments, a flow rate of the inert precursor may be less than or about 200 sccm, and may be less than or about 190 sccm, less than or about 180 sccm, less than or about 170 sccm, less than or about 160 sccm, less than or about 150 sccm, less than or about 140 sccm, less than or about 130 sccm, less than or about 120 sccm, less than or about 110 sccm, less than or about 100 sccm, or less. In embodiments, the flow rate of the inert precursor may be reduced and the flow rate of the nitrogen-containing precursor may be increased. An increased flow rate of the nitrogen-containing precursor may generate additional salts on the surfaces of the at least one layer of silicon-containing material 410 and the at least one layer of silicon-and-germanium-containing material 415 via the formation of NH₄F as will be further described below.

At operation 310, the method 300 may include forming a plasma. The plasma may be formed from the fluorine-containing precursor or precursors, the hydrogen-containing precursor, the nitrogen-containing precursor, and/or the inert precursor. The plasma may be formed in the processing region of the semiconductor processing chamber. In embodiments, the processing chamber, such as one of chambers 100 incorporated on multi-chamber processing system 10, may have two or more source plasma power sources or electrodes. The method 300 may include providing power to one or less than all of the source plasma power sources. Forming the plasma may be performed at a source plasma power of less than or about 1,000 W. Source plasma powers greater than or about 1,000 W may increase plasma temperature and etching capabilities, which may cause increased removal of silicon germanium due to salt decomposition and reduce selectivity based on increased surface reactions discussed further below. Accordingly, forming the plasma may be performed at a source plasma power of less than or about 950 W, less than or about 900 W, less than or about 850 W, less than or about 800 W, less than or about 750 W, less than or about 700 W, less than or about 650 W, less than or about 600 W, less than or about 650 W, less than or about 600 W, or lower. Additionally, source plasma powers less than or about 100 W may slow the etch process, increasing residence time of etchants, which may reduce selectivity. Accordingly, forming the plasma may be performed at a source plasma power of greater than or about 150 W, greater than or about 200 W, greater than or about 250 W, greater than or about 300 W, greater than or about 350 W, greater than or about 400 W, or more. FIG. 5B graphically depicts the representation between source plasma power and etch selectivity. As illustrated at higher source plasma powers, etch selectivity may decrease. Similarly, at lower source plasma powers, etch selectivity may decrease. Accordingly, source plasma powers between about 300 W and about 800 W may provide higher etch selectivity.

In embodiments, a bias may or may not be applied to the plasma of the carbon-containing precursor, the hydrogen-containing precursor, the nitrogen-containing precursor, and/or the inert precursor. The bias applied to the plasma of the carbon-containing precursor, the hydrogen-containing precursor, the nitrogen-containing precursor, and/or the inert precursor may be generated at a bias power of less than or about 100 W. At a bias power of greater than 100 W, the interaction between the one or more precursors and the structure 400 may become more physical and less chemical. A more physical interaction may reduce the selectivity of removal, and may result in the at least one layer of silicon-containing material 410 and the at least one layer of silicon-and-germanium-containing material 415 being removed at near equal rates, such as at an etch selectivity nearer to 1:1. Accordingly, a bias power applied to the plasma may be less than or about 90 W, less than or about 80 W, less than or about 70 W, less than or about 60 W, less than or about 50, W, less than or about 40 W, less than or about 30 W, less than or about 20 W, less than or about 10 W, or less, and in some embodiments bias may not be applied at all, which may further increase selectivity.

The plasma of the fluorine-containing precursor, the hydrogen-containing precursor, the nitrogen-containing precursor, and/or the inert precursor may be generated at a duty cycle of less than or about 50%. By operating at a duty cycle of less than or about 50%, the effective source and bias, when used, plasma powers may be reduced and may maintain the reactions as chemical reactions instead of physical reactions. Accordingly, plasma may be generated at a duty cycle of less than or about 45%, less than or about 40%, less than or about 35%, less than or about 30%, less than or about 25%, less than or about 20%, less than or about 15%, less than or about 10%, or less.

In embodiments, the method 300 may include pulsing the source plasma power while generating the plasma effluents of the precursors. In embodiments, the source plasma power may be pulsed at a frequency of less than or about 1,000 Hz, less than or about 950 Hz, less than or about 900 Hz, less than or about 850 Hz, less than or about 800 Hz, less than or about 750 Hz, less than or about 700 Hz, less than or about 650 Hz, less than or about 600 Hz, less than or about 550 Hz, less than or about 500 Hz, less than or about 450 Hz, less than or about 400 Hz, less than or about 350 Hz, less than or about 300 Hz, less than or about 250 Hz, less than or about 200 Hz, or less.

In embodiments, the plasma may be oxygen-free. In conventional technologies where oxygen may be present in the plasma, the at least one layer of silicon-containing material 410 and/or the at least one layer of silicon-and-germanium-containing material 415 may oxidize and form Si—O bonds. Si—O bonds may have a higher binding energy than Si—Si, Si—Ge, or Ge—Ge bonds and, therefore, may not be as prone to etching. If the at least one layer of silicon-containing material 410 is oxidized and forms Si—O bonds, it may be more difficult to remove the at least one layer of silicon-containing material 410 and etch selectivity may reduce. Further, the presence of oxygen may cause the at least one layer of silicon-and-germanium-containing material 415 and other materials to at least partially oxidize, which can reduce charge carrier mobility.

The plasma effluents may undergo a gas phase reaction prior to contacting the structure 400. The gas phase reaction may form intermediates that may react with the at least one layer of silicon-containing material 410 and the at least one layer of silicon-and-germanium-containing material 415. For example, the precursors may react to form a passivation compound and an etch compound. The passivation compound may include carbon, hydrogen, and fluorine materials. The passivation compound may form a material on the at least one layer of silicon-and-germanium-containing material 415. The material formed by the passivation compound may produce a porous covering, which may limit germanium removal. During removal of silicon material, some silicon may be removed through the openings or pores in the passivation material. The removal of silicon may result in an increased concentration of germanium at the surface of the at least one layer of silicon-and-germanium-containing material 415. The germanium may not as readily be removed through the passivation material. The etch compound may include nitrogen, hydrogen, and fluorine materials. The etch compound may simultaneously aid in the passivation of the at least one layer of silicon-and-germanium-containing material 415 and increase the etch selectivity of the at least one layer of silicon-containing material 410.

At operation 315, the method 300 may include contacting the at least one layer of silicon-containing material 410 and the at least one layer of silicon-and-germanium-containing material 415 with plasma effluents of the precursors, including the fluorine-containing precursor and the hydrogen-containing precursor. The nitrogen, hydrogen, and fluorine materials of the precursors may form salts, such as ammonium salts, on the at least one layer of silicon-containing material 410 and/or the at least one layer of silicon-and-germanium-containing material 415. The salt formed on the at least one layer of silicon-containing material 410 may have a lower decomposition temperature than the salt formed on the at least one layer of silicon-and-germanium-containing material 415.

For example, the salt formed on the at least one layer of silicon-containing material 410 may be or include ammonium fluorosilicate and the salt formed on the at least one layer of silicon-and-germanium-containing material 415 may be or include ammonium hexafluorogermanate. Ammonium fluorosilicate may have a standard decomposition temperature of about 130° C. and ammonium hexafluorogermanate may have a standard decomposition temperature of about 380° C. The method 300 may be carried out at a temperature and other process conditions that allows sublimation of the ammonium fluorosilicate while minimizing or preventing the ammonium hexafluorogermanate. That is, the method 300 may be carried out at a temperature, pressure, and plasma power that permits the ammonium hexafluorogermanate to remain on the at least one layer of silicon-and-germanium-containing material 415. When the method 300 is carried out at a temperature less than the decomposition temperature of ammonium fluorosilicate, the plasma may increase the temperature within the processing region such that the ammonium fluorosilicate may decompose. As the ammonium fluorosilicate sublimates, the at least one layer of silicon-containing material 410 may be etched as the ammonium fluorosilicate and the at least one layer of silicon-containing material 410 may decompose into one or more volatiles that may be subsequently purged from the processing region.

At operation 320, the method 300 may include at least partially removing or recessing the at least one layer of silicon-containing material 410. The at least one layer of silicon-containing material 410 may be removed at a higher rate than the at least one layer of silicon-and-germanium-containing material 415. The at least one layer of silicon-containing material 410 may be selectively removed relative to the at least one layer of silicon-and-germanium-containing material 415 at a rate of greater than or about 3:2. In embodiments, the at least one layer of silicon-containing material 410 may be selectively removed relative to the at least one layer of silicon-and-germanium-containing material 415 at a rate of greater than or about 2:1, greater than or about 3:1, greater than or about 4:1, greater than or about 5:1, greater than or about 6:1, greater than or about 7:1, or more.

The etch rate may be tuned depending on the flow rate of the precursors and the characteristics of the plasma power, including the source plasma power, the bias plasma power, the duty cycle, and the frequency. In embodiments, the etch rate of the at least one layer of silicon-containing material 410 may be greater than or about 15.0 Å/s, and may be greater than or about 16.0 Å/s, greater than or about 17.0 Å/s, greater than or about 18.0 Å/s, greater than or about 19.0 Å/s, greater than or about 20.0 Å/s, greater than or about 21.0 Å/s, greater than or about 22.0 Å/s, greater than or about 23.0 Å/s, greater than or about 24.0 Å/s, greater than or 5 about 25.0 Å/s, greater than or about 26.0 Å/s, greater than or about 27.0 Å/s, greater than or about 28.0 Å/s, greater than or about 29.0 Å/s, greater than or about 30.0 Å/s, or more.

During method 300, a temperature within the semiconductor processing chamber such as a substrate support temperature, or a substrate temperature, may be maintained at less than or about 125° C. At temperatures greater than 125° C., the etch byproducts for both the silicon and the silicon germanium may be volatile, increasing etching of the silicon germanium material, and etch selectivity of the at least one layer of silicon-containing material 410 relative to the at least one layer of silicon-and-germanium-containing material 415 may decrease. Accordingly, the temperature within the semiconductor processing chamber may be maintained at less than or about 120° C., less than or about 115° C., less than or about 110° C., less than or about 105° C., less than or about 100° C., less than or about 95° C., less than or about 80° C., less than or about 75° C., less than or about 70° C., less than or about 65° C., less than or about 60° C., less than or about 55° C., less than or about 50° C., or less.

Further, a pressure within the semiconductor processing chamber may be maintained at less than or about 200 mTorr. At pressures greater than 200 mTorr, the formation of plasma may be more difficult and the method 300 may be prone to generating unwanted byproducts. Further, pressures greater than 200 mTorr may cause a more isotropic etch profile and may decrease etch selectivity. Accordingly, the pressure within the semiconductor processing chamber may be maintained at less than or about 190 mTorr, less than or about 180 mTorr, less than or about 170 mTorr, less than or about 160 mTorr, less than or about 150 mTorr, less than or about 140 mTorr, less than or about 130 mTorr, less than or about 120 mTorr, less than or about 110 mTorr, less than or about 100 mTorr, less than or about 90 mTorr, less than or about 80 mTorr, less than or about 70 mTorr, less than or about 60 mTorr, less than or about 50 mTorr, less than or about 40 mTorr, less than or about 30 mTorr, less than or about 20 mTorr, less than or about 10 mTorr, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a fluorine-containing precursor” includes a plurality of such precursors, and reference to “the at least one layer of silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a fluorine-containing precursor and a hydrogen-containing precursor to a processing region of a semiconductor processing chamber, wherein a substrate is disposed within the processing region of the semiconductor processing chamber, and wherein the substrate comprises at least one layer of silicon-containing material and at least one layer of silicon-and-germanium-containing material along the substrate;
forming a plasma of the fluorine-containing precursor and the hydrogen-containing precursor within the processing region;
contacting the at least one layer of silicon-containing material and the at least one layer of silicon-and-germanium-containing material with plasma effluents of the fluorine-containing precursor and the hydrogen-containing precursor; and
removing the at least one layer of silicon-containing material at a higher rate than the at least one layer of silicon-and-germanium-containing material.

2. The semiconductor processing method of claim 1, wherein:
the fluorine-containing precursor comprises one or both of nitrogen trifluoride and carbon tetrafluoride.

3. The semiconductor processing method of claim 1, wherein:
the at least one layer of silicon-containing material is selectively removed relative to the at least one layer of silicon-and-germanium-containing material at a rate of greater than or about 2:1.

4. The semiconductor processing method of claim 1, wherein:
the plasma of the fluorine-containing precursor and the hydrogen-containing precursor is generated at a source plasma power of less than or about 1,000 W.

5. The semiconductor processing method of claim 1, wherein:
a bias applied to the plasma of the fluorine-containing precursor and the hydrogen-containing precursor is generated at a bias power of less than or about 100 W.

6. The semiconductor processing method of claim 1, wherein:
the plasma of the fluorine-containing precursor and the hydrogen-containing precursor is generated at a duty cycle of less than or about 50%.

7. The semiconductor processing method of claim 4, further comprising:
pulsing the source plasma power while forming plasma effluents of the fluorine-containing precursor and the hydrogen-containing precursor, wherein the source plasma power is pulsed at a frequency of less than or about 1000 Hz.

8. The semiconductor processing method of claim 1, wherein:
a temperature within the semiconductor processing chamber is maintained at less than or about 125° C.; and
a pressure within the semiconductor processing chamber is maintained at less than or about 200 mTorr.

9. The semiconductor processing method of claim 1, further comprising:
providing an inert precursor to the processing region of the semiconductor processing chamber with the fluorine-containing precursor and the hydrogen-containing precursor, wherein the inert precursor comprises a nitrogen-containing inert precursor, an argon-containing inert precursor, a helium-containing inert precursor, or combinations thereof.

10. The semiconductor processing method of claim 1, wherein:
a flow rate ratio of the hydrogen-containing precursor to the fluorine-containing precursor is greater than or about 2:1.

11. The semiconductor processing method of claim 1, wherein:
the plasma is oxygen-free.

12. A semiconductor processing method comprising:
providing a fluorine-containing precursor, a hydrogen-containing precursor, and a nitrogen-containing precursor;
forming a plasma of the fluorine-containing precursor, the hydrogen-containing precursor, and the nitrogen-containing precursor; and
contacting at least one layer of silicon-containing material and at least one layer of silicon-and-germanium-containing material along a substrate with plasma effluents of the fluorine-containing precursor, the hydrogen-containing precursor, and the nitrogen-containing precursor, wherein the contacting selectively removes the at least one layer of silicon-containing material.

13. The semiconductor processing method of claim 12, wherein:
the fluorine-containing precursor comprises carbon tetrafluoride; and
the nitrogen-containing precursor comprises nitrogen trifluoride.

14. The semiconductor processing method of claim 12, wherein:
the fluorine-containing precursor and the nitrogen-containing precursor form a passivation compound and an etch compound when contacting the at least one layer of silicon-containing material and the at least one layer of silicon-and-germanium-containing material, wherein the passivation compound comprises carbon, hydrogen, and fluorine materials, and wherein the etch compound comprises nitrogen, hydrogen, and fluorine materials.

15. The semiconductor processing method of claim 12, wherein:
a pressure is maintained at less than or about 70 mTorr during the semiconductor processing method.

16. The semiconductor processing method of claim 12, wherein:
the at least one layer of silicon-and-germanium-containing material is characterized by a germanium concentration of less than or about 50 at. %.

17. The semiconductor processing method of claim 14, wherein:
the etch compound removes the at least one layer of silicon-containing material relative to the at least one layer of silicon-and-germanium-containing material at a selectivity of greater than or about 3:2.

18. The semiconductor processing method of claim 12, further comprising:
providing a hydrogen-containing precursor and an inert precursor with the fluorine-containing precursor and the nitrogen-containing precursor.

19. The semiconductor processing method of claim 14, wherein:
the fluorine-containing precursor, the nitrogen-containing precursor, the hydrogen-containing precursor, and an inert precursor form the passivation compound and the etch compound;
the passivation compound passivates the at least one layer of silicon-and-germanium-containing material; and
the etch compound removes the at least one layer of silicon-containing material.

20. A semiconductor processing method comprising:
providing a fluorine-containing precursor and a nitrogen-containing precursor to a processing region of a semiconductor processing chamber, wherein a substrate is disposed within the processing region of the semiconductor processing chamber, and wherein the substrate comprises at least one layer of silicon-containing material and at least one layer of silicon-and-germanium-containing material along the substrate;
forming a plasma of the fluorine-containing precursor and the nitrogen-containing precursor within the processing region, wherein the plasma is generated at a discontinuous plasma power of less than or about 1,000 W;
contacting the at least one layer of silicon-containing material and the at least one layer of silicon-and-germanium-containing material with plasma effluents of the fluorine-containing precursor and the nitrogen-containing precursor, wherein the contacting passivates the at least one layer of silicon-and-germanium-containing material; and
removing the at least one layer of silicon-containing material at a higher rate than the at least one layer of silicon-and-germanium-containing material, wherein the at least one layer of silicon-containing material is selectively removed relative to the at least one layer of silicon-and-germanium-containing material at a rate of greater than or about 3:2.
